(19) United States
(12) Patent Application Publication
(10) Pub. No.: US 2025/0183151 A1
(43) Pub. Date: Jun. 5, 2025

(54) MIM CAPACITOR DISPOSED IN MODIFIED DUAL DAMASCENE STRUCTURE AND FABRICATING METHOD OF THE SAME

(71) Applicant: UNITED MICROELECTRONICS CORP., Hsin-Chu City (TW)

(72) Inventors: Tai-Cheng Hou, Tainan City (TW); Da-Jun LIN, Kaohsiung City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/395,760

(22) Filed: Dec. 26, 2023

(30) Foreign Application Priority Data
Dec. 1, 2023 (TW) 112146858

(51) Int. Cl. H01L 23/522; H01L 21/768

(52) U.S. Cl. CPC H01L 23/5223; H01L 21/76808; H01L 23/5226; H10D 1/042; H10D 1/714; H10D 1/716

(57) ABSTRACT

An MIM capacitor disposed in a modified dual damascene structure includes a dielectric layer, and a first modified dual damascene structure is disposed in the dielectric layer. The first modified dual damascene structure includes a trench and a hole, and the hole connects to the trench. The hole includes a funnel profile. An MIM capacitor is disposed in the first modified dual damascene structure and a first copper layer is disposed in the first modified dual damascene structure and is located on the MIM capacitor.

### BACKGROUND OF THE INVENTION

### 1. Field of the Invention

The present invention relates to a metal-insulator-metal (MIM) capacitor, and more particularly relates to an MIM capacitor disposed in a modified dual damascene structure and a fabricating method of making the same.

### 2. Description of the Prior Art

In recent years, with the development of semiconductor integrated circuit process technology, the width of components manufactured on semiconductor substrates has gradually become smaller, and the density of integrated circuits per unit area has also become higher. However, due to the increase in the density of memory cell, the space for the capacitor becomes smaller, so it is necessary to develop capacitors with small size but high capacitance.

Under high density, sufficient capacitance can be obtained by using MIM capacitors. This is one of the advantages of MIM capacitors. MIM capacitors are not only used to filter noise in radio frequency circuits, or in digital circuits. They are also widely used in general integrated circuit and circuit board manufacturing processes. Therefore, if current leakage or deformation occurs in the MIM capacitors, the IC will not be able to operate normally.

### SUMMARY OF THE INVENTION

In view of this, the present invention provides an MIM capacitor disposed in a modified dual damascene structure to solve the current leakage.

According to a preferred embodiment of the present invention, an MIM capacitor disposed in a modified dual damascene structure includes a dielectric layer. A first modified dual damascene structure is disposed in the dielectric layer. The first modified dual damascene structure includes a trench and a hole.

The hole connects to the trench and the hole includes a funnel profile. An MIM capacitor is disposed in the first modified dual damascene structure. A first copper layer is disposed in the first modified dual damascene structure and on the MIM capacitor. A fabricating method of an MIM capacitor disposed in a modified dual damascene structure includes providing a dielectric layer divided into a memory region and a logic circuit region. Next, a first dual damascene structure and a second dual damascene structure are formed in the dielectric layer, wherein the first dual damascene structure is disposed within the memory region of the dielectric layer and the second dual damascene structure is disposed within the logic circuit region of the dielectric layer. A photoresist is filled into a first hole of the first dual damascene structure and a second hole of the second dual damascene structure. Later, an oxygen-containing plasma process is performed to etch the photoresist and the dielectric layer to form a first modified dual damascene structure and a second modified dual damascene structure. Subsequently, a bottom electrode and a capacitor dielectric layer are formed to fill the first modified dual damascene structure. Finally, a barrier and a copper layer are formed to fill in the first modified dual damascene structure and the second modified dual damascene structure to form an MIM capacitor and a copper line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of an MIM capacitor disposed in a modified dual damascene structure according to a preferred embodiment of the present invention, wherein:

FIG. 1 depicts a dielectric layer with metal lines therein;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4; and

FIG. 6 is a fabricating stage in continuous of FIG. 5.

FIG. 7 shows an MIM capacitor disposed in a dual damascene structure according to an exemplary embodiment of the present invention.

### DETAILED DESCRIPTION

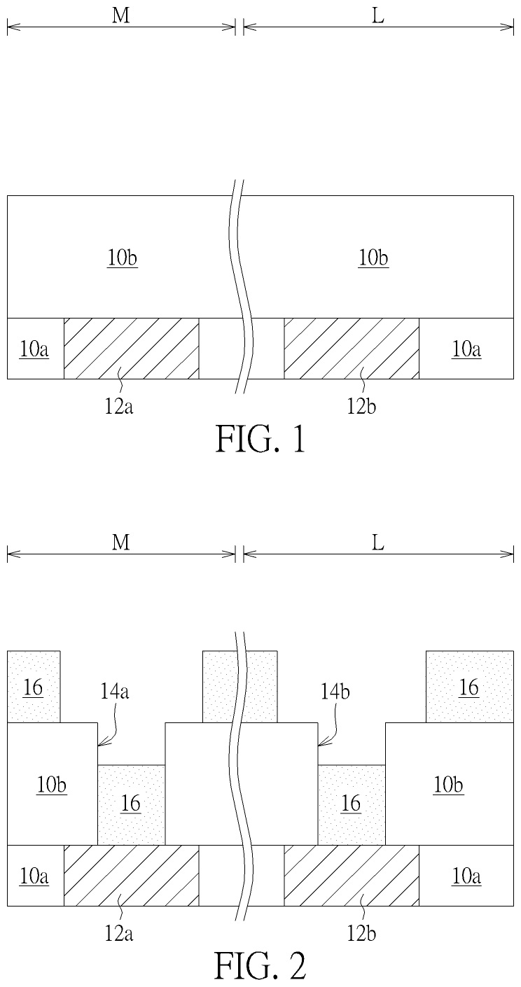

FIG. 1 to FIG. 6 depict a fabricating method of an MIM capacitor disposed in a modified dual damascene structure according to a preferred embodiment of the present invention.

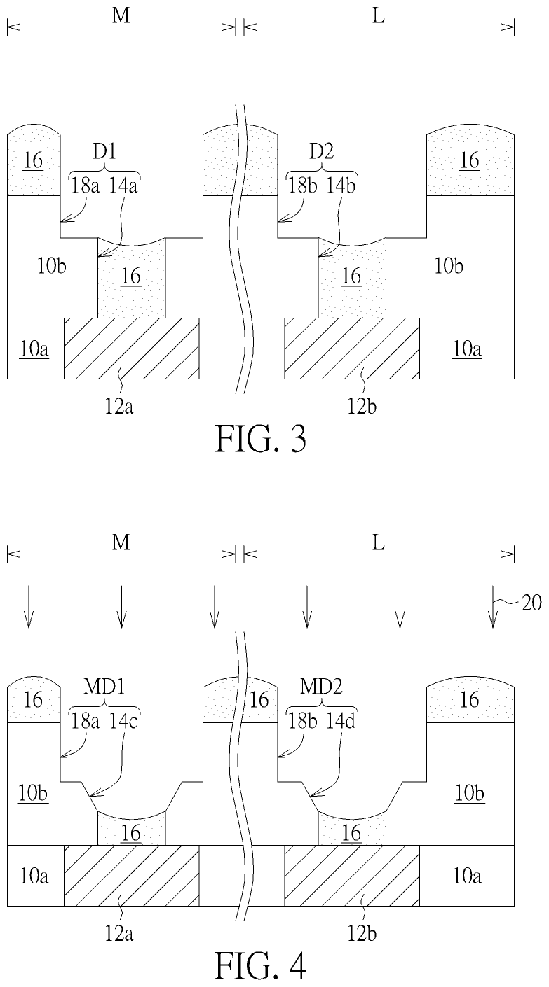

As shown in FIG. 1, a dielectric layer 10a is provided. The dielectric layer 10a is divided into a memory region M and a logic circuit region L. Metal lines 12a/12b are respectively disposed in the memory region M and the logic circuit region L of the dielectric layer 10. Then, a dielectric layer 10b is formed to cover the dielectric layer 10a. As shown in FIG. 2, the dielectric layer 10b is etched to form holes 14a/14b respectively disposed in the memory region M and the logic circuit region L to make the metal lines 12a/12b respectively exposed through the holes 14a/14b. Later, a photoresist 16 is formed to cover dielectric layer 10b and fill in holes 14a/14b. The photoresist 16 includes the location of a trench to be formed next. As shown in FIG. 3, the dielectric layer 10b is etched to form trenches 18a/18b respectively disposed in the memory area M and the logic circuit area L by taking the photoresist 16 as a mask. The trench 18a is connected to the hole 14a. The trench 18a and the hole 14a form a first dual damascene structure D1. The trench 18b and the hole 14b form a second dual damascene structure D2.

As shown in FIG. 4, an oxygen-containing plasma process 20 is performed to etch the photoresist 16 and the dielectric layer 10b to form a first modified dual damascene structure MD1 and a second modified dual damascene structure MD2. The oxygen-containing plasma process 20 uses an oxidation reaction to isotropically remove the photoresist 16. Specifically, the oxygen-containing plasma process 20 can trim the height of the photoresist 16 isotropically. When part of the height of the photoresist 16 in the holes 14a/14b is removed, the exposed sidewalls of the holes 14a/14b will also be etched by the oxygen-containing plasma, making the sidewalls of the holes 14a/14b sloping. At this time, holes 14a/14b become holes 14c/14d. According to different embodiments, the oxygen-containing plasma process 20 and an oxygen-free plasma process (not shown) may be performed alternately. The oxygen-containing plasma process 20 is specifically used to adjust the height of the photoresist 16, and the oxygen-free plasma process is specifically used to etch the dielectric layer 16b. The oxygen-free plasma processes can be an anisotropic etching performed by only inert gas.

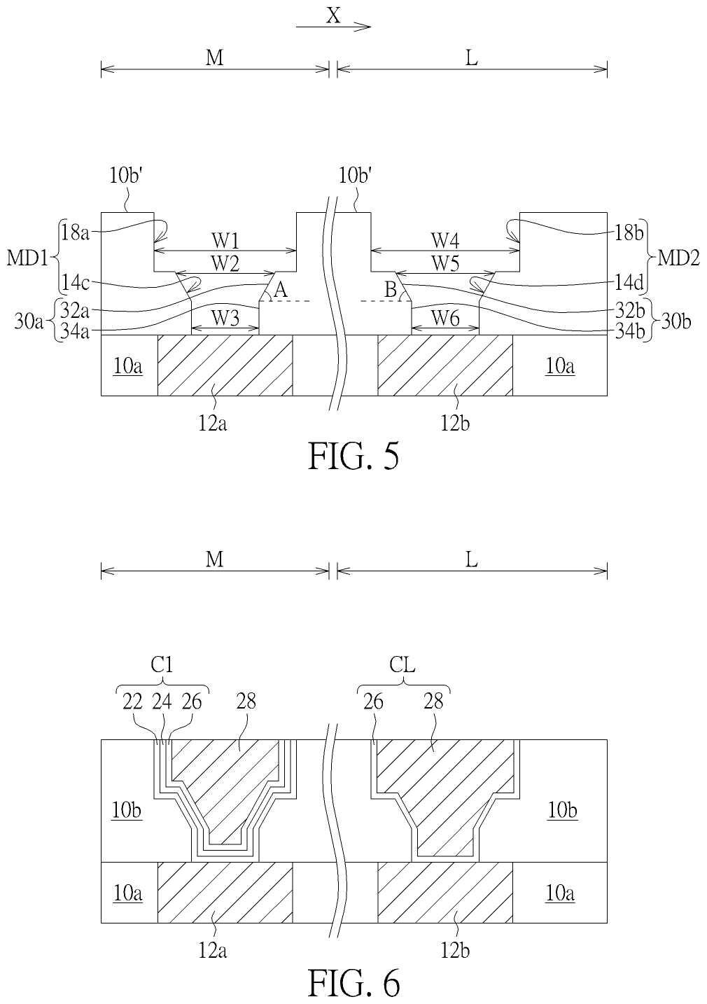

As shown in FIG. 5, the photoresist 16 is completely removed. As shown in FIG. 6, a bottom electrode 22 and a capacitor dielectric layer 24 are sequentially formed to cover the first modified dual damascene structure MD1, the second modified dual damascene structure MD2 and a top surface of the dielectric layer 10b. Then, the bottom electrode 22 and the capacitor dielectric layer 24 in the second modified dual damascene structure MD2 are removed. Later, a barrier 26 and a copper layer 28 are formed to fill the first modified dual damascene structure MD1 and the second modified dual damascene structure MD2. Then, the copper layer 28, the barrier 26, the capacitor dielectric layer 24 and the bottom electrode 22 outside of the first modified dual damascene structure MD1 and the second modified dual damascene structure MD2 are removed to form an MIM capacitor C1 and a copper line CL. It is noteworthy that the barrier 26 in the first modified dual damascene structure MD1 serves as the top electrode in the MIM capacitor C1.

As shown in FIG. 5 and FIG. 6, an MIM capacitor C1 disposed in a modified dual damascene structure MD1 includes a dielectric layer 10b. The dielectric layer 10b is divided into a memory region M and a logic circuit region L. A first modified dual damascene structure MD1 is disposed in the memory region M of the dielectric layer 10b, and a second modified dual damascene structure MD2 is disposed in the logic circuit region L of the dielectric layer 10b. A profile of the second modified dual damascene structure MD2 is the same as a profile of the first modified dual damascene structure MD1. An MIM capacitor C1 is disposed in the first modified dual damascene structure MD1. A copper layer 28 is disposed in the first modified dual damascene structure MD1 and on the MIM capacitor C1. A barrier 26 covers the second modified dual damascene structure MD2, and a copper layer 28 covers the barrier 26.

The MIM capacitor C1 includes a top electrode (the barrier 26), a capacitor dielectric layer 24 and a bottom electrode 22 stacked in sequence from bottom to top. The top electrode and the barrier 26 are made of the same material by the same step. The top electrode includes tantalum nitride or titanium nitride, that is, the barrier 26 includes tantalum nitride or titanium nitride. Moreover, the bottom electrode 22 includes tantalum or titanium. The capacitor dielectric layer 24 includes aluminum oxide, zirconium oxide, barium strontium titanate (BST), lead zirconate titanate (PZT), zirconium silicate (ZrSiO₄), silicon hafnium oxide (HfSiO₂), silicon hafnium oxynitride (HfSiON), tantalum oxide or a combination of the above materials.

Furthermore, the first modified dual damascene structure MD1 includes a trench 18a and a hole 14c. The hole 14c connects to the trench 18a. The hole 14c includes a funnel profile 30a. The trench 18a is disposed on the hole 14c. The funnel profile 30a includes a wide hole 32a and a narrow hole 34a. The width W2 of the wide hole 32a is greater than the width W3 of the narrow hole 34a. The width W2 of the wide hole 32a is smaller than the width W1 of the bottom of the trench 18a. The wide hole 32a connects the trench 18a and the narrow hole 34a. The wide hole 32a converges from the trench 18a to the narrow hole 34a. The wide hole 32a includes a slope. The slope faces the dielectric layer 10b. The dielectric layer 10b includes a top surface 10b′. A horizontal direction X is parallel to the top surface 10b′, and there is an angle A disposed between the slope and the horizontal direction X. The angle A is between 60 and 80 degrees.

Similarly, the second modified dual damascene structure MD2 includes a trench 18b and a hole 14d. The hole 14d connects to the trench 18b. The hole 14d includes a funnel profile 30b. The trench 18b is disposed on the hole 14d. A width W5 of the wide hole 32b of the funnel profile 30b is also greater than the width W6 of the narrow hole 34b. The wide hole 32b connects the trench 18b and the narrow hole 34b. The wide hole 32b converges from the trench 18b to the narrow hole 34b. There is also an angle B between a slope of the wide hole 32b and the horizontal direction X. The angle B is between 60 and 80 degrees.

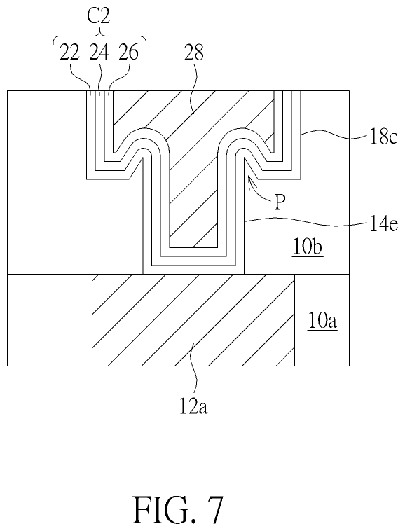

FIG. 7 shows an MIM capacitor disposed in a dual damascene structure according to an exemplary embodiment of the present invention, wherein elements which are substantially the same as those in the embodiment of FIG. 5 and FIG. 6 are denoted by the same reference numerals; an accompanying explanation is therefore omitted.

The difference between the MIM capacitor C2 in FIG. 7 and the MIM capacitor C1 in FIG. 6 is that the MIM capacitor C2 has a pointed angle P at the connection between the trench 18c and the hole 14e. This is because when making the dual damascene structure of MIM capacitor C2, the oxygen-containing plasma process is not applied to etch the photoresist, only the oxygen-free plasma process is used. In this way, the photoresist will only be etched anisotropically, therefore a pointed angle P is formed. Current leakage occurs at the pointed angle P of the MIM capacitor C2. Regarding the MIM capacitor C1 in FIG. 6, the pointed angle is removed and the slope is formed. The slope increases the capacitor area and therefore the capacitance is raised, and the slope can prevent the above-mentioned current leakage. In addition, because the width W5 of the wide hole 32b is smaller than the width W4 of the bottom of the trench 18b, this ensures that the resistance of the copper line CL in the trench 18b will not be greatly affected by the funnel profile 30b below. Furthermore, the manufacturing process of the MIM capacitor C1 can be compatible with the manufacturing process of the copper dual damascene structure in the logic circuit area L. In this way, the capacitance can be increased and the fabricating steps are also simplified.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A metal-insulator-metal (MIM) capacitor disposed in a modified dual damascene structure, comprising:
a dielectric layer;
a first modified dual damascene structure disposed in the dielectric layer, wherein the first modified dual damascene structure comprises:
a trench;
a hole, wherein the hole connects to the trench, the hole comprises a funnel profile;
an MIM capacitor disposed in the first modified dual damascene structure; and
a first copper layer disposed in the first modified dual damascene structure and on the MIM capacitor.

2. The MIM capacitor disposed in a modified dual damascene structure of claim 1, wherein the funnel profile comprises a wide hole and a narrow hole, and a width of the wide hole is greater than a width of the narrow hole.

3. The MIM capacitor disposed in a modified dual damascene structure of claim 2, wherein the wide hole connects the trench and the narrow hole, and the wide hole converges from the trench to the narrow hole.

4. The MIM capacitor disposed in a modified dual damascene structure of claim 2, wherein the wide hole comprises a slope, the slope faces the dielectric layer, the dielectric layer comprises a top surface, a horizontal direction is parallel to the top surface, there is an angle disposed between the slope and the horizontal direction, and the angle is between 60 and 80 degrees.

5. The MIM capacitor disposed in a modified dual damascene structure of claim 1, further comprising:
a second modified dual damascene structure disposed in the dielectric layer, wherein a profile of the second modified dual damascene structure is the same as a profile of the first modified dual damascene structure;
a barrier covering the second modified dual damascene structure; and
a second copper layer covering the barrier.

6. The MIM capacitor disposed in a modified dual damascene structure of claim 5, the MIM capacitor comprises an top electrode, a capacitor dielectric layer and a bottom electrode stacked in sequence from bottom to top, and the top electrode and the barrier are made of the same material.

7. The MIM capacitor disposed in a modified dual damascene structure of claim 6, wherein the top electrode comprises tantalum nitride or titanium nitride and the bottom electrode comprises tantalum or titanium.

8. The MIM capacitor disposed in a modified dual damascene structure of claim 1, wherein the trench is disposed on the hole.

9. A fabricating method of a metal-insulator-metal (MIM) capacitor disposed in a modified dual damascene structure, comprising:
providing a dielectric layer divided into a memory region and a logic circuit region;
forming a first dual damascene structure and a second dual damascene structure in the dielectric layer, wherein the first dual damascene structure is disposed within the memory region of the dielectric layer and the second dual damascene structure is disposed within the logic circuit region of the dielectric layer, a photoresist is filled into a first hole of the first dual damascene structure and a second hole of the second dual damascene structure;
performing an oxygen-containing plasma process to etch the photoresist and the dielectric layer to form a first modified dual damascene structure and a second modified dual damascene structure;
forming a bottom electrode and a capacitor dielectric layer to fill the first modified dual damascene structure; and
forming a barrier and a copper layer to fill in the first modified dual damascene structure and the second modified dual damascene structure to form an MIM capacitor and a copper line.

10. The fabricating method of an MIM capacitor disposed in a modified dual damascene structure of claim 9, wherein fabricating steps of the bottom electrode and the capacitor dielectric layer comprise:
forming the bottom electrode and the capacitor dielectric layer to cover the first modified dual damascene structure and the second modified dual damascene structure; and
removing the bottom electrode and the capacitor dielectric layer within the second modified dual damascene structure.

11. The fabricating method of an MIM capacitor disposed in a modified dual damascene structure of claim 9, the first modified dual damascene structure comprises a first trench and a third hole, the third hole comprises a first funnel profile, the second modified dual damascene structure comprises a second trench and a fourth hole, and the fourth hole comprises a second funnel profile.

12. The fabricating method of an MIM capacitor disposed in a modified dual damascene structure of claim 11, wherein the first funnel profile comprises a first wide hole and a first narrow hole, a width of the first wide hole is greater than a width of the first narrow hole, the second funnel profile comprises a second wide hole and a second narrow hole, and a width of the second wide hole is greater than a width of the second narrow hole.

13. The fabricating method of an MIM capacitor disposed in a modified dual damascene structure of claim 12, wherein the first wide hole comprises a first slope, the second wide hole comprises a second slope, the first slope and the second slope face the dielectric layer, the dielectric layer comprises a top surface, a horizontal direction is parallel to the top surface, a first angle is disposed between the first slope and the horizontal direction, a second angle is disposed between the second slope and the horizontal direction, the first angle is between 60 and 80 degrees and the second angle is between 60 and 80 degrees.
